(19) United States
(12) Patent Application Publication
(10) Pub. No.: US 2018/0180924 A1
(43) Pub. Date: Jun. 28, 2018

(54) ARRAY SUBSTRATE, LIQUID CRYSTAL DISPLAY PANEL AND MANUFACTURE METHOD OF LIQUID CRYSTAL DISPLAY PANEL

(71) Applicant: Wuhan China Star Optoelectronics Technology Co., Ltd., Wuhan, Hubei (CN)

(72) Inventors: Shihpo CHOU, Shenzhen, Guangdong (CN); Yao-li HUANG, Shenzhen, Guangdong (CN); Xinglong HE, Shenzhen, Guangdong (CN)

(73) Assignee: Wuhan China Star Optoelectronics Technology Co., L td., Wuhan, Hubei (CN)

(21) Appl. No.: 15/323,946

(22) PCT Filed: Nov. 21, 2016
(86) PCT No.: PCT/CN2016/106599

§ 371 Date: Jan. 4, 2017

(30) Foreign Application Priority Data
Nov. 4, 2016 (CN) 201610970518.7

(51) Int. Cl. G02F 1/1345; G02F 1/1333; G02F 1/1339; G02F 1/1335; G02F 1/1368; H01L 27/12

(52) U.S. Cl. CPC G02F 1/13452; G02F 1/13338; G02F 1/13394; G02F 1/133514; G02F 2001/133354; G02F 1/133305; G02F 1/1368; H01L 27/1218; G02F 2001/13396; G02F 1/133512

(57) ABSTRACT

The present invention discloses an array substrate, comprising a first flexible substrate, and the first flexible substrate comprises an integrally formed display region and a non display region around the display region, and a display circuit layer is formed on the display region, and a transmission circuit layer is formed on the non display region, and one end of the transmission circuit layer is electrically coupled to the display circuit layer, and the other end of the transmission circuit layer is employed to be electrically coupled to a control integration circuit. The electrical connection of the array substrate and the control integration circuit according to the present invention is reliable so that the liquid crystal panel utilizing the array substrate can normally display. The present invention further discloses a liquid crystal display panel and a manufacture method of a liquid crystal display panel.

### CROSS REFERENCE

This application claims the priority of Chinese Patent Application No. 201610970518.7, entitled “Array substrate, liquid crystal display panel and manufacture method of liquid crystal display panel”, filed on Nov. 4 , 2016, the disclosure of which is incorporated herein by reference in its entirety.

### FIELD OF THE INVENTION

The present invention relates to a display device technology field, and more particularly to an array substrate, a liquid crystal display panel and a manufacture method of a liquid crystal display panel.

### BACKGROUND OF THE INVENTION

With the high speed development of the technology, the flat panel display device, particularly the Liquid Crystal Display (LCD) has been widely utilized in the consumer products, such as the cell phone, the notebook, the laptop and the television and gradually replaced the Cathode Ray Tube (CRT) for becoming the mainstream of the display device because of the merits of high image quality, small volume, light weight and wide application scope.

The liquid crystal display panel is the most important component in the liquid crystal display, which generally comprises a Thin Film Transistor (TFT) substrate (or array substrate), a Color Filter (CF) substrate (or color film substrate) and a liquid crystal layer sandwiched between the two substrates. The liquid crystal display panel is coupled to the control integration circuit on the system main board and the array substrate through the Flexible Printed Circuit (FPC) so that an electric field is created at the circuit on the array substrate, and thus to control the orientation of the liquid crystal molecules to change the transmission rate of the liquid crystal display panel for achieving the display function. However, as laminating the flexible circuit board onto the array substrate, the electrical connection of the array substrate and the control integration circuit may not be reliable due to the lamination misalignment or the insecure lamination and thus to result in the abnormal display of the liquid crystal display panel.

### SUMMARY OF THE INVENTION

An objective of the present invention is to provide an array substrate that the electrical connection of the array substrate and the control integration circuit is reliable so that the liquid crystal panel utilizing the array substrate can normally display.

Besides, the present invention further provides a liquid crystal display panel.

Moreover, the present invention further provides a manufacture method of a liquid crystal display panel.

For realizing the aforesaid objective, the technical solution utilized by the embodiments of the present invention is:

On the one hand, provided is an array substrate, comprising a first flexible substrate, and the first flexible substrate comprises an integrally formed display region and a non display region around the display region, and a display circuit layer is formed on the display region, and a transmission circuit layer is formed on the non display region, and one end of the transmission circuit layer is electrically coupled to the display circuit layer, and the other end of the transmission circuit layer is employed to be electrically coupled to a control integration circuit.

On the other hand, further provided is a liquid crystal display panel, comprising:

an array substrate, comprising a first flexible substrate, wherein the first flexible substrate comprises an integrally formed display region and a non display region around the display region, and a display circuit layer is formed on the display region, and a transmission circuit layer is formed on the non display region, and one end of the transmission circuit layer is electrically coupled to the display circuit layer, and the other end of the transmission circuit layer is employed to be electrically coupled to a control integration circuit;

a color film substrate, being located at one side of the display circuit layer away from the display region and right in front of the display region, and the color film substrate comprising a second flexible substrate; and

a liquid crystal layer, located between the color film substrate and the array substrate.

The liquid crystal display panel further comprises a drive integration circuit, and the drive integration circuit is formed on the non display region and is electrically coupled to the display circuit layer through the transmission circuit layer.

The liquid crystal display panel further comprises a backlight module, and the backlight module is located at one side of the array substrate away from the color film substrate, and the backlight module is electrically coupled to the transmission circuit layer through a flexible circuit board.

The color film substrate further comprises a color filter layer, and the color filter layer is formed at one side of the second flexible substrate facing toward the liquid crystal layer, and the color filter layer comprises a black matrix and a color matrix which are alternately located;

the liquid crystal display panel further comprises a first set of support columns, and the first set of support columns is located between the color film substrate and the array substrate, and right in front of the black matrix.

The liquid crystal display panel further comprises a second set of support columns, and the second set of support columns is located between the color film substrate and the array substrate, and right in front of the black matrix;

in a display direction of the liquid crystal display panel, a length of the second set of support columns is smaller than a length of the first set of support columns.

The first set of support columns comprises a plurality of first support columns, and the second set of support columns comprises a plurality of second support columns, and the plurality of first support columns and the plurality of second support columns are alternately aligned.

The display circuit layer comprises a display circuit and a touch control circuit, and the display circuit is employed to control liquid crystal twist of the liquid crystal layer, and the touch control circuit is employed to receive a touch control action of a user.

The liquid crystal display panel further comprises a shielding layer, and the shielding layer is located at one side of the color film substrate away from the array substrate.

On the other hand, further provided is a manufacture method of a liquid crystal display panel, wherein the manufacture method comprises:

providing an array substrate, wherein the array substrate comprises a first flexible substrate, and the first flexible substrate comprises an integrally formed display region and a non display region around the display region, and a display circuit layer is formed on the display region, and a transmission circuit layer is formed on the non display region, and one end of the transmission circuit layer is electrically coupled to the display circuit layer, and the other end of the transmission circuit layer is employed to be electrically coupled to a control integration circuit;

forming a side frame on the transmission circuit layer;

filling liquid crystal inside the side frame to form a liquid crystal layer; and

providing a color film substrate including a second flexible substrate to aligning the color film substrate and the array substrate to form cell, and the color film substrate, being located at one side of the liquid crystal layer away from the array substrate and right in front of the display region.

Compared with prior art, the present invention possesses benefits below:

the non display region and the transmission circuit layer of the first flexible substrate are equivalent to a flexible circuit board, and the non display region and the display region are integrally formed, thus the array substrate of the liquid crystal display panel has its own flexible circuit board and the array substrate can be directly to be coupled to the control integration circuit to eliminate the lamination process of the flexible circuit board and the array substrate in prior art and to prevent the lamination misalignment or the insecure lamination. The electrical connection relationship of the array substrate and the control integration circuit is reliable, and the liquid crystal display panel can normally perform display. Because the liquid crystal display panel no longer requires the flexible circuit board coupled to the array substrate and the control integration circuit and the cost of independently manufacturing the flexible circuit board is saved, the cost of the liquid crystal display panel is reduced, accordingly.

Because the array substrate utilizes the first flexible substrate to be the carrier and the color film substrate utilizes the second flexible substrate to be the carrier, the liquid crystal display panel can be bent and the application scope is wider.

### BRIEF DESCRIPTION OF THE DRAWINGS

In order to more clearly illustrate the embodiments of the present invention, the following figures will be described in the embodiments are briefly introduced. It is obvious that the drawings are only some embodiments of the present invention, those of ordinary skill in this field can obtain other figures according to these figures without paying the premise.

FIG. 1 is a structure diagram of a liquid crystal display panel provided by the embodiment of the present invention.

FIG. 2 is a structure diagram of an array substrate of a liquid crystal display panel provided by the embodiment of the present invention.

FIG. 3 is a structure diagram of a color film substrate of a liquid crystal display panel provided by the embodiment of the present invention.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

Besides, the following descriptions for the respective embodiments are specific embodiments capable of being implemented for illustrations of the present invention with referring to appended figures. For example, the terms of up, down, front, rear, left, right, interior, exterior, side, etcetera are merely directions of referring to appended figures. Therefore, the wordings of directions are employed for explaining and understanding the present invention but not limitations thereto.

In the description of the application, which needs explanation is that the term “installation”, “connected”, “connection”, “located on . . . ” should be broadly understood unless those are clearly defined and limited, otherwise, For example, those can be a fixed connection, a detachable connection, or an integral connection; those can be a mechanical connection, or an electrical connection; those can be a direct connection, or an indirect connection with an intermediary, which may be an internal connection of two elements. To those of ordinary skill in the art, the specific meaning of the above terminology in the present invention can be understood in the specific circumstances.

Besides, in the description of the present invention, unless with being indicated otherwise, “plurality” means two or more. In the present specification, the term “process” encompasses an independent process, as well as a process that cannot be clearly distinguished from another process but yet achieves the expected effect of the process of interest. Moreover, in the present specification, any numerical range expressed herein using “to” refers to a range including the numerical values before and after “to” as the minimum and maximum values, respectively. In figures, the same reference numbers will be used to refer to the same or like parts.

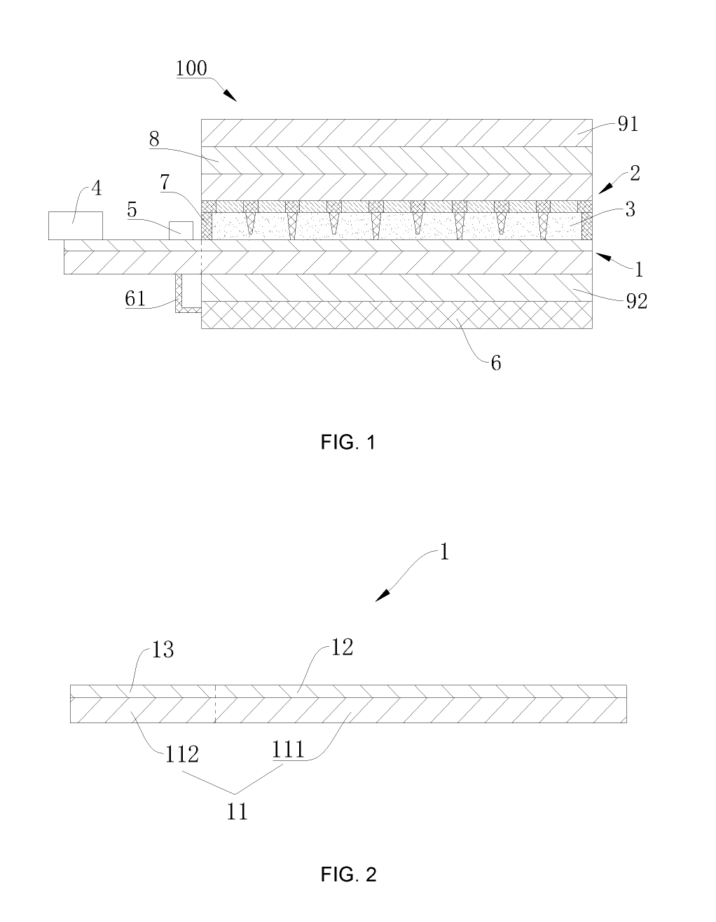

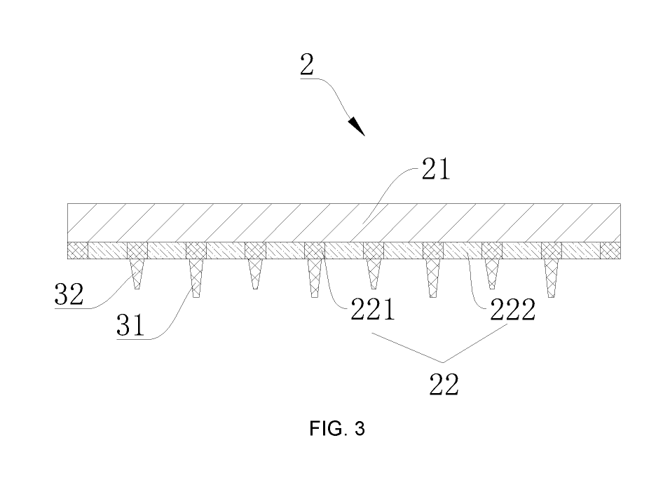

Please refer from FIG. 1 to FIG. 3, the embodiment of the present invention provides a liquid crystal display panel 100, comprising an array substrate 1, a color film substrate 2 and a liquid crystal layer 3. The array substrate 1 comprises a first flexible substrate 11, and the first flexible substrate 11 comprises an integrally formed display region 111 and a non display region 112 around the display region 111. A display circuit layer 12 is formed on the display region 111, and a transmission circuit layer 13 is formed on the non display region 112, and one end of the transmission circuit layer 13 is electrically coupled to the display circuit layer 12, and the other end of the transmission circuit layer 13 is employed to be electrically coupled to a control integration circuit 4. A color film substrate 2 is located at one side of the display circuit layer 12 away from the display region 111 and right in front of the display region 111, and the color film substrate 2 comprises a second flexible substrate 21. The liquid crystal layer 3 is located between the color film substrate 2 and the array substrate 1. When the liquid crystal display panel 100 performs display, the transmission circuit layer 13 receives the display signals sent by the control integration circuit 4, and the display circuit layer 12 controls the orientation of the liquid crystal in the liquid crystal layer 3 according to the display signal, and thus the liquid crystal display panel 100 shows the images corresponding to the display signals.

In this embodiment, the non display region 112 and the transmission circuit layer 13 of the first flexible substrate 11 are equivalent to a flexible circuit board, and the non display region 112 and the display region 111 are integrally formed, thus the array substrate 1 of the liquid crystal display panel 100 has its own flexible circuit board and the array substrate 1 can be directly to be coupled to the control integration circuit 4 to eliminate the lamination process of the flexible circuit board and the array substrate in prior art and to prevent the lamination misalignment or the insecure lamination. The electrical connection relationship of the array substrate 1 and the control integration circuit 4 is reliable, and the liquid crystal display panel 100 can normally perform display. Because the liquid crystal display panel 100 no longer requires the flexible circuit board coupled to the array substrate 1 and the control integration circuit 4 and the cost of independently manufacturing the flexible circuit board is saved, the cost of the liquid crystal display panel 100 is reduced, accordingly.

Because the array substrate 1 utilizes the first flexible substrate 11 to be the carrier and the color film substrate 2 utilizes the second flexible substrate 21 to be the carrier, the liquid crystal display panel 100 can be bent and the application scope is wider.

Preferably, while manufacturing the display circuit layer 12, the transmission circuit layer 13 is formed so that the connection relationship of the transmission circuit layer 13 and the display circuit layer 12 is more reliable and the manufacture cost of the array substrate 1 is low. The display circuit layer 12 and the transmission circuit layer 13 can be manufactured by utilizing the photolithography process.

It is understandable that the display circuit layer 12 comprises a display pixel array. The display pixels are controlled by the signals on the gate lines and the data lines which are intersectant. Each of the display pixels comprises an electrode structure applying an electric field to the liquid crystal layer 3. The display pixel comprises a thin film transistor, employed to control the electric filed applied by the electrode structure. The thin film transistor, the gate line, the data line and other conductive lines are integrated inside the display circuit layer 12.

Preferably, the first flexible substrate 11 and the second flexible substrate 21 can be manufactured by the transparent flexible materials, which include Polyimide (PI) and the Polyethylene terephthalate (PET) but not limited thereto.

Furthermore, referring to FIG. 1 and FIG. 2, as being a selectable embodiment, the liquid crystal display panel 100 further comprises a drive integration circuit 5. The drive integration circuit 5 is formed on the non display region 112 and is electrically coupled to the display circuit layer 12 through the transmission circuit layer 13. Then, the transmission circuit layer 13 connects the drive integration circuit 5 with the display layer circuit, and also connects the drive integration circuit 5 with the control integration circuit 4.

When the liquid crystal display panel 100 performs display, the transmission circuit layer 13 receives the display signals sent by the control integration circuit 4, and the drive integration circuit 5 receives the display signals and converts the same into the voltage signals, and the transmission circuit layer 13 transmits the voltage signals to the display circuit layer 12, and the display circuit layer 12 controls the orientation of the liquid crystal in the liquid crystal layer 3, and thus to show the images corresponding to the display signals.

In this embodiment, because the drive integration circuit 5 is formed on the non display region 112, the area of the display region 111 of the first flexible circuit board can be reduced to achieve the miniaturization design for the liquid crystal display panel 100.

It is understandable that because the first flexible substrate 11 can be bent, the non display region 112 can be bent to arbitrary position (for instance, one side of the display region 111 away from the display circuit layer 12), and thus to reduce the frame body volume of the liquid crystal display panel 100. The frame body is employed to wrap the outer side of the display module (and the backlight module) of the liquid crystal display panel 100.

Furthermore, referring to FIG. 1 and FIG. 2, as being a selectable embodiment, the liquid crystal display panel 100 further comprises a backlight module 6. The backlight module 6 is located at one side of the array substrate 1 away from the color film substrate 2, and the backlight module 6 is electrically coupled to the transmission circuit layer 13 through a flexible circuit board 61, and the transmission circuit layer 13 provides a light source to the backlight module 6.

Furthermore, referring from FIG. 1 to FIG. 3, as being a selectable embodiment, the color film substrate 2 further comprises a color filter layer 22, and the color filter layer 22 is formed at one side of the second flexible substrate 21 facing toward the liquid crystal layer 3. The color filter layer 22 comprises a black matrix 221 and a color matrix 222 which are alternately located. The color matrix 222 can convert the outgoing light of the liquid crystal display panel 100 into color lights. The liquid crystal display panel 100 further comprises a first set of support columns 31, and the first set of support columns 31 is located between the color film substrate 2 and the array substrate 1, and right in front of the black matrix 221. The first set of support columns 31 can prevent the collapse occurring between the color film substrate 2 and the array substrate 1.

Preferably, the liquid crystal display panel 100 further comprises a second set of support columns 32, and the second set of support columns 32 is located between the color film substrate 2 and the array substrate 1, and right in front of the black matrix 221. In a display direction of the liquid crystal display panel 100, a length of the second set of support columns 32 is smaller than a length of the first set of support columns 31.

When the user does not apply an external force or applies a smaller external force to the liquid crystal display panel 100, the first set of support columns 31 acts the support function to the color film substrate 2 and the array substrate 1. When the user applies a larger external force to the liquid crystal display panel 100, the first set of support columns 31 is forced and contracted. The first set of support columns 31 and the second set of support columns 32 support together between the color film substrate 2 and the array substrate 1, and thus to prevent the liquid crystal display panel 100 from being over pressed.

Preferably, the first set of support columns 31 comprises a plurality of first support columns. The second set of support columns 32 comprises a plurality of second support columns. The plurality of first support columns and the plurality of second support columns are alternately aligned. The plurality of first support columns and the plurality of second support columns can be alternately aligned in kinds of arrangements, such as one by one, one by two or two by one.

Preferably, the liquid crystal display panel 100 further comprises a side frame 7 connected between the array substrate 1 and the color film substrate 2, and the liquid crystal layer 3 is formed inside the side frame 7. The side frame 7 can seal the liquid crystal layer 3 and also can support the array substrate 1 and the color film substrate 2.

Furthermore, as being a selectable embodiment, the display circuit layer 12 comprises a display circuit and a touch control circuit, and the display circuit is employed to control liquid crystal orientation of the liquid crystal layer 3, and the touch control circuit is employed to receive a touch control action of a user. Then, the liquid crystal display panel 100 is an In-cell type touch panel.

Furthermore, referring to FIG. 1, as being a selectable embodiment, the liquid crystal display panel 100 further comprises a shielding layer 8, and the shielding layer 8 is located at one side of the color film substrate 2 away from the array substrate 1. The shielding layer 8 can protect the display function and the touch control function of the liquid crystal display panel 100 from the external electrostatic interference.

Preferably, the shielding layer 8 can utilize ITO (Indium tin oxide), Graphene or PEDOT (3,4-ethylenedioxythiophene).

Furthermore, referring to FIG. 1, as being a selectable embodiment, a first polarizer 91 is located at one side of the color film substrate 2 away from the array substrate 1. A second polarizer 92 is further located at one side of the array substrate away from the color film substrate 2. The first polarizer 91 and the second polarizer 92 are employed to filter the polarized light. The direction of the polarization axis of the first polarizer 91 is perpendicular with the direction of the polarization axis of the second polarizer 92.

Please refer from FIG. 1 to FIG. 3. The embodiment of the present invention further provides a manufacture method of a liquid crystal display panel, which can be employed to the liquid crystal display panel 100 of any foregoing embodiments. The manufacture method of the liquid crystal display panel comprises:

Step 1: manufacturing an array substrate 1, wherein the array substrate 1 comprises a first flexible substrate 11, and the first flexible substrate 11 comprises an integrally formed display region 111 and a non display region 112 around the display region 111, and a display circuit layer 12 is formed on the display region 111, and a transmission circuit layer 13 is formed on the non display region 112, and one end of the transmission circuit layer 13 is electrically coupled to the display circuit layer 12, and the other end of the transmission circuit layer 13 is employed to be electrically coupled to a control integration circuit 4;

Step 2: forming a side frame 7 on the transmission circuit layer 13;

Step 3: filling liquid crystal inside the side frame 7 to form a liquid crystal layer 3; and

Step 4: providing a color film substrate 2 including a second flexible substrate 21 to aligning the color film substrate 2 and the array substrate 1 to form cell, and the color film substrate 2 is located at one side of the liquid crystal layer 3 away from the array substrate 1 and right in front of the display region 111.

In this embodiment, the array substrate 1 manufactured by the manufacture method of the liquid crystal display panel has its own flexible circuit board and the lamination process of the flexible circuit board and the array substrate in prior art can be eliminated to prevent the lamination misalignment or the insecure lamination. The electrical connection relationship of the array substrate 1 and the control integration circuit 4 is reliable, and the liquid crystal display panel 100 can normally perform display. Because the flexible circuit board coupled to the array substrate 1 and the control integration circuit 4 is no longer required and the cost of independently manufacturing the flexible circuit board is saved, the cost of the liquid crystal display panel 100 is reduced, accordingly.

Preferably, in step 1, due to manufacturing the display circuit layer 12 and the transmission circuit layer 13 at the same time, the connection relationship of the transmission circuit layer 13 and the display circuit layer 12 is more reliable and the manufacture cost of the array substrate 1 is low. The display circuit layer 12 and the transmission circuit layer 13 can be manufactured by utilizing the photolithography process.

Preferably, in step 4, the color film substrate 2 further comprises a color filter layer 22, and the color filter layer 22 is formed at one side of the second flexible substrate 21 facing toward the liquid crystal layer 3. The color filter layer 22 comprises a black matrix 221 and a color matrix 222 which are alternately located. a first set of support columns 31 and a second set of support columns 32 are formed at one side of the black matrix 221 facing to the array substrate. The first set of support columns 31 supports between the array substrate 1 and the color film substrate 2, and employed to prevent the collapse occurring to the liquid crystal display panel 100. In a display direction of the liquid crystal display panel 100, a length of the second set of support columns 32 is smaller than a length of the first set of support columns 31. The second set of support columns 32 is employed to together act the support function with the first set of support columns 31 under circumstance that the first set of support columns 31 is compressed.

Furthermore, as being a selectable embodiment, the manufacture method of the liquid crystal display panel 100 further comprises:

Step 5: adhering a shielding layer 8 at one side of the color film substrate 2 away from the array substrate 1;

Step 6: adhering a first polarizer 91 at one side of the shielding layer 8 away from the color film substrate 2, and adhering a second polarizer 92 at one side of the array substrate 1 away from the color film substrate 2;

Step 7: adhering a backlight module 6 at one side of the second polarizer 92 away from the array substrate 1, and the backlight module 6 being electrically coupled to the transmission circuit layer 13 through the flexible circuit board 61.

The detail description has been introduced above for the embodiment of the invention. Herein, a specific case is applied in this article for explain the principles and specific embodiments of the present invention have been set forth. The description of the aforesaid embodiments is only used to help understand the method of the present invention and the core idea thereof; meanwhile, for those of ordinary skill in the art, according to the idea of the present invention, there should be changes either in the specific embodiments and applications but in sum, the contents of the specification should not be limitation to the present invention.

What is claimed is:

1. An array substrate, wherein the array substrate comprises a first flexible substrate, and the first flexible substrate comprises an integrally formed display region and a non display region around the display region, and a display circuit layer is formed on the display region, and a transmission circuit layer is formed on the non display region, and one end of the transmission circuit layer is electrically coupled to the display circuit layer, and the other end of the transmission circuit layer is employed to be electrically coupled to a control integration circuit.

2. A liquid crystal display panel, wherein the liquid crystal display panel comprises:
an array substrate, comprising a first flexible substrate, wherein the first flexible substrate comprises an integrally formed display region and a non display region around the display region, and a display circuit layer is formed on the display region, and a transmission circuit layer is formed on the non display region, and one end of the transmission circuit layer is electrically coupled to the display circuit layer, and the other end of the transmission circuit layer is employed to be electrically coupled to a control integration circuit;
a color film substrate, being located at one side of the display circuit layer away from the display region and right in front of the display region, and the color film substrate comprising a second flexible substrate; and
a liquid crystal layer, located between the color film substrate and the array substrate.

3. The liquid crystal display panel according to claim 2, wherein the liquid crystal display panel further comprises a drive integration circuit, and the drive integration circuit is formed on the non display region and is electrically coupled to the display circuit layer through the transmission circuit layer.

4. The liquid crystal display panel according to claim 2, wherein the liquid crystal display panel further comprises a backlight module, and the backlight module is located at one side of the array substrate away from the color film substrate, and the backlight module is electrically coupled to the transmission circuit layer through a flexible circuit board.

5. The liquid crystal display panel according to claim 2, wherein the color film substrate further comprises a color filter layer, and the color filter layer is formed at one side of the second flexible substrate facing toward the liquid crystal layer, and the color filter layer comprises a black matrix and a color matrix which are alternately located;
the liquid crystal display panel further comprises a first set of support columns, and the first set of support columns is located between the color film substrate and the array substrate, and right in front of the black matrix.

6. The liquid crystal display panel according to claim 5, wherein the liquid crystal display panel further comprises a second set of support columns, and the second set of support columns is located between the color film substrate and the array substrate, and right in front of the black matrix;
in a display direction of the liquid crystal display panel, a length of the second set of support columns is smaller than a length of the first set of support columns.

7. The liquid crystal display panel according to claim 6, wherein the first set of support columns comprises a plurality of first support columns, and the second set of support columns comprises a plurality of second support columns, and the plurality of first support columns and the plurality of second support columns are alternately aligned.

8. The liquid crystal display panel according to claim 2, wherein the display circuit layer comprises a display circuit and a touch control circuit, and the display circuit is employed to control liquid crystal orientation of the liquid crystal layer, and the touch control circuit is employed to receive a touch control action of a user.

9. The liquid crystal display panel according to claim 2, wherein the liquid crystal display panel further comprises a shielding layer, and the shielding layer is located at one side of the color film substrate away from the array substrate.

10. The liquid crystal display panel according to claim 8, wherein the liquid crystal display panel further comprises a shielding layer, and the shielding layer is located at one side of the color film substrate away from the array substrate.

11. A manufacture method of a liquid crystal display panel, wherein the manufacture method comprises:
providing an array substrate, wherein the array substrate comprises a first flexible substrate, and the first flexible substrate comprises an integrally formed display region and a non display region around the display region, and a display circuit layer is formed on the display region, and a transmission circuit layer is formed on the non display region, and one end of the transmission circuit layer is electrically coupled to the display circuit layer, and the other end of the transmission circuit layer is employed to be electrically coupled to a control integration circuit;
forming a side frame on the transmission circuit layer;
filling liquid crystal inside the side frame to form a liquid crystal layer; and
providing a color film substrate including a second flexible substrate to aligning the color film substrate and the array substrate to form cell, and the color film substrate, being located at one side of the liquid crystal layer away from the array substrate and right in front of the display region.
